(19) United States
(12) Patent Application Publication
(10) Pub. No.: US 2009/0040842 A1
(43) Pub. Date: Feb. 12, 2009

(54) Enhanced write abort mechanism for non-volatile memory

(75) Inventors: Steven T. Sprouse, San Jose, CA (US); Dhaval Parikh, Santa Clara, CA (US); Arjun Kapoor, San Francisco, CA (US)

Correspondence Address: BRINKS HOFER GILSON & LIONE/SanDisk, P.O. BOX 10395, CHICAGO, IL, 60610, US

(73) Assignee: SanDisk Corporation, a Delaware Corporation

(21) Appl. No.: 11/890,708

(22) Filed: Aug. 6, 2007

(51) Int. Cl. G11C 7/00

(52) U.S. Cl. 365/189.16

(57) ABSTRACT

In a non-volatile memory (NVM) device having a controller and a non-volatile memory array controlled by the controller a voltage supervisor circuit monitors an output of a voltage supply powering the NVM device. The voltage supervisor circuit may be part of the NVM device or coupled to it. The voltage supervisor circuit is configured to assert a “low-voltage” signal responsive to detecting the output of the voltage supply powering the NVM device dropping below a predetermined value. The controller is configured to write data into the memory array while the “low-voltage” signal is deasserted and to suspend writing data while the “low-voltage” signal is asserted. In response to assertion of the “low-voltage” signal, the controller completes a write cycle/program operation, if pending, and prevents any additional write cycles/program operation(s) during assertion of the “low-voltage” signal.

### STATEMENT OF RELATED APPLICATIONS

The present application may be considered to be related to co-pending U.S. patent application Ser. No. 11/______ filed on even date herewith (Attorney Docket No. SDA-1181X (060589-004), in the name of inventors Steven T. Sprouse, Dhaval Parikh and Arjun Kapoor, entitled “Enhanced Write Abort Mechanism for Non-Volatile Memory”, commonly owned herewith.

### TECHNICAL FIELD

The present disclosure relates generally to write abort mechanisms for use with non-volatile memory.

### BACKGROUND

Binary and Multi-Level Cell (MLC) NAND Flash Memory are forms of non-volatile memory (NVM) that are capable of high data storage densities and high performance, however, a power failure due to hot removal, brownout, blackout or the like can cause data corruption or loss due to the nature of the way in which data is written to this type of memory. Typically a “page” or group of bits at a time is written to the NVM. If a power failure occurs during a write cycle/program operation, something less than all of the bits of the page may be programmed successfully in the NVM. When the page containing unsuccessfully programmed bits is read back, some bits will have the new value, some will have the old value and, as a result, the page will be corrupted. In some prior approaches, complex data structures and multiple copies of host data are kept on the NVM device to ensure graceful recovery under most circumstances. This approach, unfortunately, reduces performance and data storage densities. An NVM program cycle using Flash-type memory, for example, typically takes on the order of 0.5-10 mSec, depending upon the type of memory.

This problem can be addressed through the use of a backup or secondary power source arranged to directly power the NVM such as a battery or very large-valued capacitor (on the order of 1000's of uF), but these solutions are often costly or require too much space. An improved solution would be desirable.

### OVERVIEW

In a non-volatile memory (NVM) device having a controller and a non-volatile memory array controlled by the controller a voltage supervisor circuit monitors an output of a voltage supply powering the NVM device. The voltage supervisor circuit may be part of the NVM device or coupled to it. The voltage supervisor circuit is configured to assert a “low-voltage” signal responsive to detecting the output of the voltage supply powering the NVM device dropping below a predetermined value. The controller is configured to write data into the memory array while the “low-voltage” signal is deasserted and to suspend writing data while the “low-voltage” signal is asserted. In response to assertion of the “low-voltage” signal, the controller completes a write cycle/NVM program operation, if pending, and prevents any additional write cycles/program operation(s) during assertion of the “low-voltage” signal.

### BRIEF DESCRIPTION OF THE DRAWINGS

The accompanying drawings, which are incorporated into and constitute a part of this specification, illustrate one or more examples of embodiments and, together with the description of example embodiments, serve to explain the principles and implementations of the embodiments.

In the drawings:

FIG. 1 is a voltage/time plot which illustrates graphically a power-off profile for one typical power supply from a personal computer.

FIG. 2 is a similar voltage/time plot which illustrates graphically a power-off profile for another typical power supply from a personal computer.

FIG. 3 illustrates a schematic block diagram of a non-volatile (NVM) memory device coupled to a host in accordance with one embodiment.

FIG. 4 illustrates an ideal voltage/time plot and the time available for completing a pending write operation in accordance with one embodiment.

### DESCRIPTION OF EXAMPLE EMBODIMENTS

Example embodiments are described herein in the context of a non-volatile memory device of the type having a controller controlling the reading and writing of data from/to an associated non-volatile memory array. Those of ordinary skill in the art will realize that the following description is illustrative only and is not intended to be in any way limiting. Other embodiments will readily suggest themselves to such skilled persons having the benefit of this disclosure. Reference will now be made in detail to implementations of the example embodiments as illustrated in the accompanying drawings. The same reference indicators will be used throughout the drawings and the following description to refer to the same or like items.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

In accordance with this disclosure, the components, process steps, and/or data structures described herein may be implemented using various types of operating systems, computing platforms, computer programs, and/or general purpose machines. In addition, those of ordinary skill in the art will recognize that devices of a less general purpose nature, such as hardwired devices, field programmable gate arrays (FPGAs), application specific integrated circuits (ASICs), or the like, may also be used without departing from the scope and spirit of the inventive concepts disclosed herein. Where a method comprising a series of process steps is implemented by a computer or a machine and those process steps can be stored as a series of instructions readable by the machine, they may be stored on a tangible medium such as a computer memory device (e.g., ROM (Read Only Memory), PROM (Programmable Read Only Memory), EEPROM (Electrically Eraseable Programmable Read Only Memory), FLASH Memory, Jump Drive, and the like), magnetic storage medium (e.g., tape, magnetic disk drive, and the like), optical storage medium (e.g., CD-ROM, DVD-ROM, paper card, paper tape and the like) and other types of program memory.

In embedded applications of NVM, where hot removal is not a substantial issue (e.g., due to the memory device being relatively inaccessible, soldered in place, or the like) it is possible to leverage the inherent capacitance of the system (e.g., power supply capacitors and printed circuit board capacitance) to allow for successful completion of “pending” or in-process NVM program or write cycle.

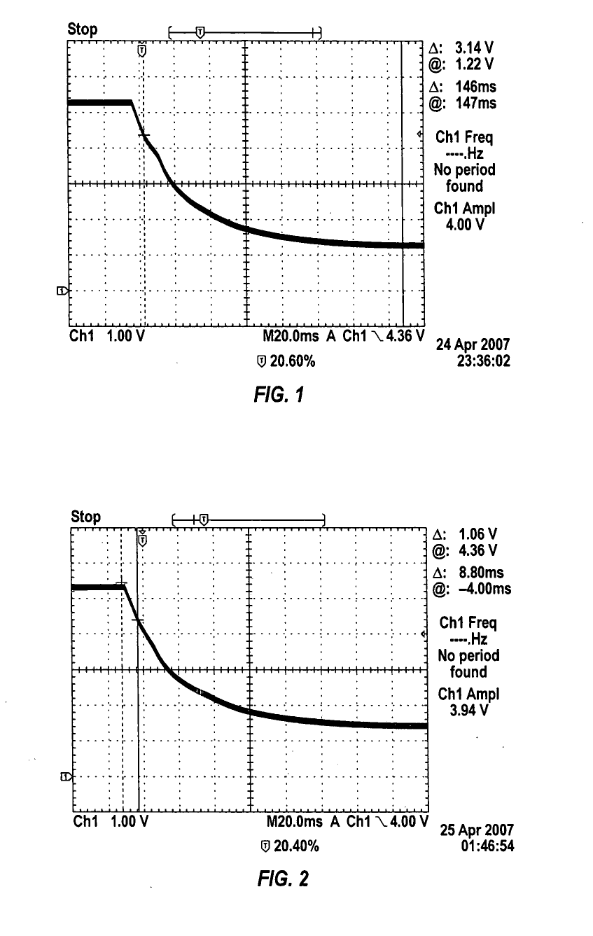

Turning to FIGS. 1 and 2, FIG. 1 is a voltage/time plot which graphically illustrates a power-off profile for one typical power supply from a personal computer. FIG. 2 is a similar voltage/time plot which graphically illustrates a power-off profile for another typical power supply from a personal computer. In each case, the vertical scales are 1 Volt DC (VDC) per division and the horizontal scales are 20 mSec per division. Of interest is the fact that upon being turned off, the power supply is able to hold the voltage for almost two divisions, then the voltage starts to drop. The voltage spends approximately 25 mSec in the voltage range between 4.5 VDC and 2.7 VDC. In one embodiment it is expected that NVM should be able to complete a write cycle/program operation in approximately 0.5-5 mSec, thus if the memory were to complete a current write cycle/program operation and begin no other write cycles/program operation(s) while the power was interrupted, data corruption problems could be obviated in such applications of NVM.

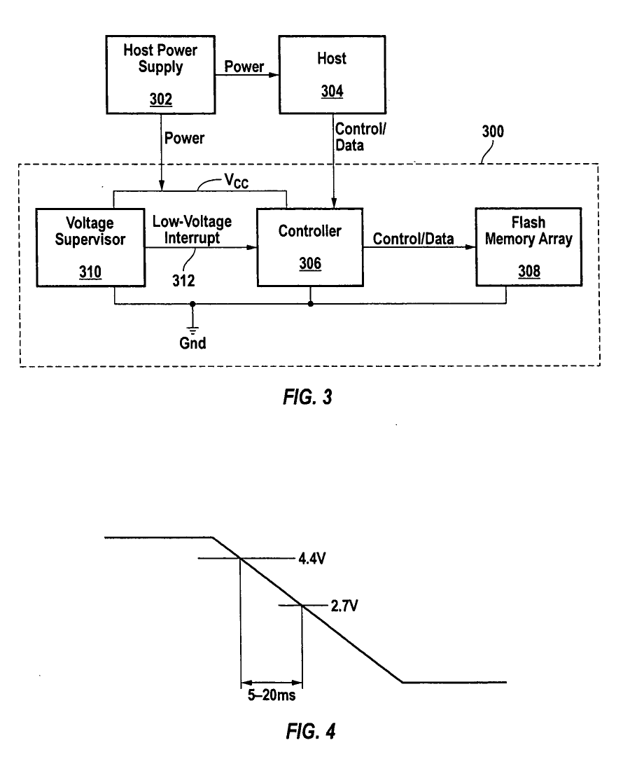

To utilize this feature of large power supplies, a voltage supervisor circuit 304, as shown in FIG. 3, is used to detect when the voltage has dropped significantly—here to a predetermined level of below 4.5 VDC (from just above 5.0 VDC). At that point, the voltage supervisor circuit is configured to assert a “low voltage signal” indicative of the below normal voltage output of the power supply to alert the NVM controller to suspend further writes to the NVM memory array. This approach takes full advantage of the fact that even though the specified Vcc_min is 4.5 VDC, the controller and memory will continue to function (in one embodiment) until the voltage drops to approximately 2.7 VDC. If the ramp down rate is sufficiently low, as shown in FIG. 4, e.g., 4.4 VDC to 2.7 VDC in about 5-20 mSec in one embodiment, then there will be enough time to complete a pending write cycle/program operation and further write cycles/program operation(s) will be suspended while the “low-voltage” signal continues to be asserted by the voltage supervisor circuit 304. Implementation of the voltage supervisor circuit 304 may be made in any convenient manner known to those of skill in the art.

In FIG. 3 a system bock diagram illustrates a configuration of an NVM device 300 coupled to a host power supply 302 and a host device 304. The host power supply 302 and host device 304 are of conventional design. The NVM device 300 comprises a non-volatile memory controller 306, flash memory array 308 and voltage supervisor circuit 310. Upon detecting an output voltage of the power supply (Vcc-GND) lower than a predetermined value (here we use the example 4.4 VDC in a 5 VDC system), the voltage supervisor circuit 310 in one embodiment asserts a “low-voltage” signal or “interrupt” on line 312. The controller 306, responsive to the assertion of this signal, completes any pending (e.g., already started) write cycles/NVM program operation and then (in one embodiment) executes a repetitive algorithm or loop to repetitively check to see if the low-voltage signal has been deasserted, as would occur if a blackout/brownout resolved itself before causing a complete power shutdown. The result of running this repetitive algorithm is to lock up the controller 306 so that no further write cycles/program operation(s) may be started (without causing it to reset). Of course, if the power is not restored, the controller 306 will eventually reset due to lack of power, but because many power glitches are quickly resolved, this approach protects the memory contents while avoiding unnecessary resets. In another embodiment, the “low-voltage” signal is applied as a standard flash memory control signal known as the “ready/busy” or “rb” signal. In accordance with this approach, if the voltage supervisor 310 were to detect a low-voltage condition and thus assert this signal, the flash memory array 308 would complete any pending write cycles/program operation(s), and internally it would deassert its “ready/busy” line to signal to the controller 306 that it was ready to execute another command (e.g., another write). However, the voltage supervisor 310, by asserting “ready/busy” to the controller 306, can, in effect, override the signal from the flash memory array 308 and thereby prevent the memory from effectively signaling that it is ready. In this way controller 306 is tricked into concluding that the memory is still busy (i.e., until the voltage supervisor 310 deasserts “ready/busy” to the controller 306).

In accordance with various embodiments, the voltage supervisor circuit 304 may be external to a package (such as, for example, a multi-chip module or other packaging technology supporting and interconnecting multiple circuit components) or die (i.e., a die from a semiconductor wafer) comprising the flash memory array 308 and controller 306 (the package or die receiving the low-voltage signal via an electrical coupling to the external voltage supervisor 310), or the voltage supervisor circuit 310 may be integrated into a package or die comprising the flash memory array 308 and controller 306, the voltage supervisor circuit 310 implemented as a part of the package or die itself, receiving the +Vcc and GND power signals from a power supply which is external to the package or die (e.g., from a host power supply 302). Similarly, the flash memory array 308 and the voltage supervisor 310 may be integrated together into a single package or die and coupled to an external controller 306. In such an implementation, a low-voltage condition is detected at the package/die comprising the array/voltage supervisor and the voltage supervisor signals back to the external controller 306. It is also contemplated that the controller 306 and voltage supervisor 310 may be integrated together in a single package/die apart from the flash memory array 308.

Note that in the implementation shown in FIG. 3, power line Vcc is not provided directly to flash memory array 308 but power provided to the flash memory array 308 is provided from controller 306 through the control/data line coupling controller 306 to flash memory array 308.

While embodiments and applications have been shown and described, it would be apparent to those skilled in the art having the benefit of this disclosure that many more modifications than mentioned above are possible without departing from the inventive concepts disclosed herein. The invention, therefore, is not to be restricted except in the spirit of the appended claims.

What is claimed is:

1. A non-volatile memory apparatus, comprising:
a non-volatile memory array;
a memory controller configured to receive from a voltage supervisor circuit configured for monitoring an output of a voltage supply powering the apparatus, the voltage supervisor circuit configured to assert a “low-voltage” signal responsive to detecting the output of the voltage supply dropping below a predetermined value, the memory controller also configured to communicate with the memory array and configured to write data into the memory array while the “low-voltage” signal is deasserted and to suspend writing data in response to assertion of the “low-voltage” signal.

2. The apparatus of claim 1, wherein the non-volatile memory array, memory controller and voltage supervisor circuit are integrated into a single package.

3. The apparatus of claim 1, wherein the non-volatile memory array, memory controller and voltage supervisor circuit are integrated into a single die.

4. The apparatus of claim 1, wherein the non-volatile memory array and memory controller are integrated into a single package and the voltage supervisor circuit is external to that package.

5. The apparatus of claim 1, wherein the non-volatile memory array and memory controller are integrated into a single die and the voltage supervisor circuit is external to that die.

6. The apparatus of claim 1, wherein the non-volatile memory array and the voltage supervisor circuit are integrated into a single package and the memory controller is external to that package.

7. The apparatus of claim 1, wherein the non-volatile memory array and the voltage supervisor circuit are integrated into a single die and the memory controller is external to that die.

8. The apparatus of claim 1, wherein the voltage supervisor circuit and the memory controller are integrated into a single package and the non-volatile memory array is external to that package.

9. The memory system of claim 1, wherein the voltage supervisor circuit and the memory controller are integrated into a single die and the non-volatile memory array is external to that die.

10. The apparatus of claim 1, wherein the controller is configured to suspend writing data in response to the execution of a repetitive algorithm which includes checking the status of the “low-voltage” signal until the “low-voltage” signal is deasserted.

11. The apparatus of claim 2, wherein the controller is configured to suspend writing data in response to the execution of a repetitive algorithm which includes checking the status of the “low-voltage” signal until the “low-voltage” signal is deasserted.

12. The apparatus of claim 3, wherein the controller is configured to suspend writing data in response to the execution of a repetitive algorithm which includes checking the status of the “low-voltage” signal until the “low-voltage” signal is deasserted.

13. The apparatus of claim 4, wherein the controller is configured to suspend writing data in response to the execution of a repetitive algorithm which includes checking the status of the “low-voltage” signal until the “low-voltage” signal is deasserted.

14. The apparatus of claim 5, wherein the controller is configured to suspend writing data in response to the execution of a repetitive algorithm which includes checking the status of the “low-voltage” signal until the “low-voltage” signal is deasserted.

15. The apparatus of claim 6, wherein the controller is configured to suspend writing data in response to the execution of a repetitive algorithm which includes checking the status of the “low-voltage” signal until the “low-voltage” signal is deasserted.

16. The apparatus of claim 7, wherein the controller is configured to suspend writing data in response to the execution of a repetitive algorithm which includes checking the status of the “low-voltage” signal until the “low-voltage” signal is deasserted.

17. The apparatus of claim 8, wherein the controller is configured to suspend writing data in response to the execution of a repetitive algorithm which includes checking the status of the “low-voltage” signal until the “low-voltage” signal is deasserted.

18. The apparatus of claim 9, wherein the controller is configured to suspend writing data in response to the execution of a repetitive algorithm which includes checking the status of the “low-voltage” signal until the “low-voltage” signal is deasserted.

19. The apparatus of claim 1, wherein the controller is configured to suspend writing data in response to the assertion of the “low-voltage” signal on a ready/busy signal line of the controller until the “low-voltage” signal is deasserted.

20. The apparatus of claim 2, wherein the controller is configured to suspend writing data in response to the assertion of the “low-voltage” signal on a ready/busy signal line of the controller until the “low-voltage” signal is deasserted.

21. The apparatus of claim 3, wherein the controller is configured to suspend writing data in response to the assertion of the “low-voltage” signal on a ready/busy signal line of the controller until the “low-voltage” signal is deasserted.

22. The apparatus of claim 4, wherein the controller is configured to suspend writing data in response to the assertion of the “low-voltage” signal on a ready/busy signal line of the controller until the “low-voltage” signal is deasserted.

23. The apparatus of claim 5, wherein the controller is configured to suspend writing data in response to the assertion of the “low-voltage” signal on a ready/busy signal line of the controller until the “low-voltage” signal is deasserted.

24. The apparatus of claim 6, wherein the controller is configured to suspend writing data in response to the assertion of the “low-voltage” signal on a ready/busy signal line of the controller until the “low-voltage” signal is deasserted.

25. The apparatus of claim 7, wherein the controller is configured to suspend writing data in response to the assertion of the “low-voltage” signal on a ready/busy signal line of the controller until the “low-voltage” signal is deasserted.

26. The apparatus of claim 8, wherein the controller is configured to suspend writing data in response to the assertion of the “low-voltage” signal on a ready/busy signal line of the controller until the “low-voltage” signal is deasserted.

27. The apparatus of claim 9, wherein the controller is configured to suspend writing data in response to the assertion of the “low-voltage” signal on a ready/busy signal line of the controller until the “low-voltage” signal is deasserted.
